(19) United States
(12) Patent Application Publication
(10) Pub. No.: US 2024/0081071 A1
(43) Pub. Date: Mar. 7, 2024

(54) MEMORY DEVICE AND MANUFACTURING METHOD OF THE MEMORY DEVICE

(71) Applicant: SK hynix Inc., Icheon-si Gyeonggi-do (KR)

(72) Inventors: Jung Shik JANG, Icheon-si Gyeonggi-do (KR); Mi Seong PARK, Icheon-si Gyeonggi-do (KR); In Su PARK, Icheon-si Gyeonggi-do (KR); Won Geun CHOI, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 18/114,878

(22) Filed: Feb. 27, 2023

(30) Foreign Application Priority Data
Sep. 2, 2022 (KR) 10-2022-0111228

(51) Int. Cl. H10B 43/35; H10B 43/27

(52) U.S. Cl. CPC H10B 43/35; H10B 43/27

(57) ABSTRACT

There are provided a memory device and a manufacturing method of the memory device. The memory device includes: a first stack structure including a word line of a first group and select lines of a first group; a second stack structure including select lines of a second group; a first plug in the first stack structure; a second plug connected to the first plug, the second plug being disposed in the second stack structure; a first isolation pattern between the select lines of the first group; and a second isolation pattern between the select lines of the second group.

### CROSS-REFERENCE TO RELATED APPLICATION

The present application claims priority under 35 U.S.C. § 119(a) to Korean patent application number 10-2022-0111228, filed on Sep. 2, 2022, in the Korean Intellectual Property Office, the entire disclosure of which is incorporated herein by reference.

### BACKGROUND

### 1. Technical Field

The present disclosure generally relates to a memory device and a manufacturing method of the memory device, and more particularly, to a three-dimensional memory device and a manufacturing method of the three-dimensional memory device.

### 2. Related Art

A memory device may be classified into a volatile memory device in which stored data disappears when the supply of power is interrupted and a nonvolatile memory device in which stored data is retained even when the supply of power is interrupted.

The nonvolatile memory device may include a NAND flash memory, a NOR flash memory, a resistive random access memory (ReRAM), a phase-change random access memory (PRAM), a magnetoresistive random access memory (MRAM), a ferroelectric random access memory (FRAM), a spin transfer torque random access memory (STT-RAM), and the like.

A NAND flash memory system may include a memory device configured to store data and a controller configured to control the memory device. The memory device may include a memory cell array in which data is stored and peripheral circuits configured to perform a program, read or erase operation in response to a command transmitted from the controller.

The memory cell array may include a plurality of memory blocks, and each of the plurality of memory blocks may include a plurality of memory cells.

As the degree of integration of memory devices increases, a memory device capable of storing large-capacity data is required, and simplification of manufacturing processes is required to reduce manufacturing cost.

### SUMMARY

In accordance with an aspect of the present disclosure, there may be provided a memory device including: a first stack structure including a word line of a first group and select lines of a first group, which are isolated from each other on the word line of the first group; a second stack structure including select lines of a second group, which are isolated from each other on the select lines of the first group, and a word line of a second group on the select lines of the second group; a first plug in the first stack structure; a second plug connected to the first plug, the second plug being disposed in the second stack structure; a first isolation pattern between the select lines of the first group; and a second isolation pattern between the select lines of the second group, wherein the select lines of the first group include a first select line of a first group and a second select line of a first group, which respectively surround a first side portion and a second side portion of the first plug at both sides of the first isolation pattern, and wherein the select lines of the second group include a first select line of a second group and a second select line of a second group, which respectively surround a first side portion and a second side portion of the second plug at both sides of the second isolation pattern.

In accordance with another aspect of the present disclosure, there may be provided a method of manufacturing a memory device, the method including: forming, on a lower structure, a first stack structure including word lines of a first group and select lines of a first group, which are isolated from each other on the word lines of the first group; forming a first isolation pattern isolating the select lines of the first group from each other; forming a first plug overlapping with the first isolation pattern in the first stack structure; forming, on the first stack structure, a first sub-structure including select lines of a second group, which are isolated from each other; forming a second isolation pattern isolating the select lines of the second group from each other; and forming, above the select lines of the second group, a second sub-structure including word lines of a second group and select lines of a third group, which are isolated from each other.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

FIG. 1 is a diagram illustrating a memory device in accordance with an embodiment of the present disclosure.

FIG. 2 is a diagram illustrating an arrangement structure of a memory cell array and a peripheral circuit.

FIG. 3 is a diagram illustrating a structure of the memory cell array.

FIGS. 4A and 4B are views illustrating layouts of a memory device in accordance with an embodiment of the present disclosure.

FIGS. 5A and 5B are views illustrating sections of a memory device in accordance with an embodiment of the present disclosure.

FIG. 6A is a circuit diagram illustrating a structure of strings in accordance with an embodiment of the present disclosure.

FIG. 6B is a diagram illustrating voltages applied to gate lines in a program operation in accordance with an embodiment of the present disclosure.

FIG. 6C is a diagram illustrating voltages applied to the gate lines in a read operation in accordance with an embodiment of the present disclosure.

FIGS. 7A, 7B, 7C, 7D, 7E, 7F, 7G, 7H, 7I, 7J, 7K, 7L, 7M, 7N, and 7O are sectional views illustrating a manufacturing method of a memory device in accordance with an embodiment of the present disclosure.

FIG. 8 is a sectional view illustrating a memory device in accordance with another embodiment of the present disclosure.

FIG. 9 is a diagram illustrating a Solid State Drive (SSD) system to which the memory device of the present disclosure is applied.

FIG. 10 is a diagram illustrating a memory card system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Various embodiments may provide a memory device and a manufacturing method of the memory device, which can improve the degree of integration of the memory device.

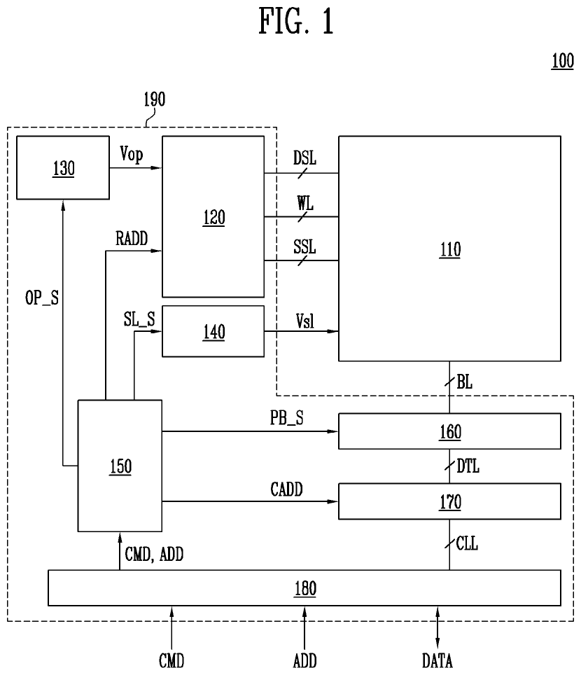

FIG. 1 is a diagram illustrating a memory device in accordance with an embodiment of the present disclosure.

Referring to FIG. 1, the memory device 100 may include a peripheral circuit 190 and a memory cell array 110.

The peripheral circuit 190 may be configured to perform a program operation and a verify operation, which are used to store data, to perform a read operation for outputting data stored in the memory cell array 110, or to perform an erase operation for erasing data stored in the memory cell array 110. The peripheral circuit 190 may include a voltage generating circuit 130, a row decoder 120, a source line driver 140, a control circuit 150, a page buffer 160, a column decoder 170, and an input/output circuit 180.

The memory cell array 110 may include a plurality of memory cells in which data is stored. In an embodiment, the memory cell array 110 may include a three-dimensional memory cell array. The plurality of memory cells may store single-bit data or multi-bit data of two or more bits according to a program manner. The plurality of memory cells may constitute a plurality of strings. Memory cells included in each of the strings may be electrically connected to each other through a channel. Channels included in the strings may be connected to the page buffer 160 through bit lines BL.

The voltage generating circuit 130 may generate various operating voltages Vop used for a program operation, a read operation, or an erase operation in response to an operation signal OP_S. For example, the voltage generating circuit 130 may selectively generate and output the operating voltages Vop including a program voltage, a verify voltage, a pass voltage, a read voltage, an erase voltage, and the like.

The row decoder 120 may be connected to the memory cell array 110 through a plurality of drain select lines DSL, a plurality of word lines WL, and a plurality of source select lines SSL. The row decoder 120 may transfer the operating voltages Vop to the plurality of drain select lines DSL, the plurality of word lines WL, and the plurality of source select lines SSL in response to a row address RADD.

The source line driver 140 may transmit a source voltage Vsl to the memory cell array 110 in response to a source line control signal SL_S. For example, the source voltage Vsl may be transferred to a source line connected to the memory cell array 110.

The control circuit 150 may output the operation signal OP_S, the row address RADD, the source line control signal SL_S, a page buffer control signal PB_S, and a column address CADD, in response to a command CMD and an address ADD.

The page buffer 160 may be connected to the memory cell array 110 through the bit lines BL. The page buffer 160 may store data DATA received through a plurality of bit lines BL in response to the page buffer control signal PB_S. The page buffer 160 may sense a voltage or current of the plurality of bit lines BL in a read operation.

The column decoder 170 may transmit data DATA input from the input/output circuit 180 to the page buffer 160 or transmit data DATA stored in the page buffer 160 to the input/output circuit 180, in response to the column address CADD. The column decoder 170 may exchange data DATA with the input/output circuit 180 through column lines CLL, and exchange data DATA with the page buffer 160 through data lines DTL.

The input/output circuit 180 may transfer, to the control circuit 150, a command CMD and an address ADD, which are transferred from an external device (e.g., a controller) connected to the memory device 100, and output data received from the column decoder 170 to the external device.

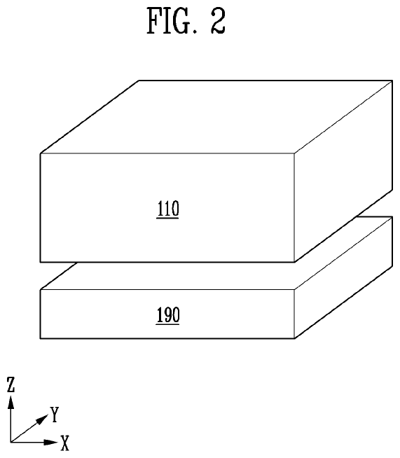

FIG. 2 is a diagram illustrating an arrangement structure of the memory cell array and the peripheral circuit.

Referring to FIG. 2, the memory cell array 110 may be stacked above the peripheral circuit 190. For example, when a substrate forms an X-Y plane, the peripheral circuit 190 may be stacked in a Z direction from the substrate, and the memory cell array 110 may be stacked above the peripheral circuit 190.

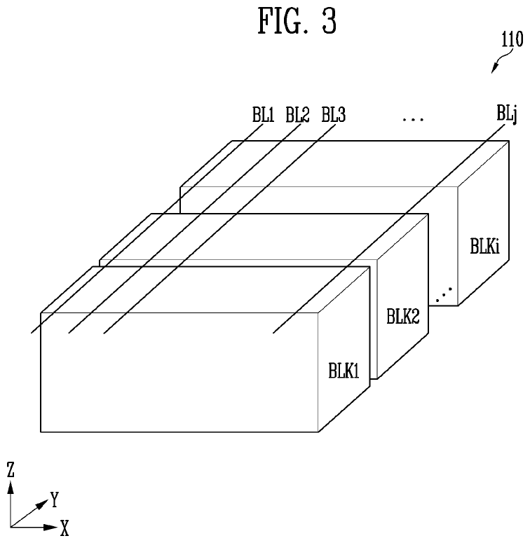

FIG. 3 is a diagram illustrating a structure of the memory cell array.

Referring to FIG. 3, the memory cell array 110 may include first to ith memory blocks BLK1 to BLKi (i is a positive integer). The first to ith memory blocks BLK1 to BLKi may be arranged to be spaced apart from each other along a Y direction, and be commonly connected to first to ith bit lines BL1 to BLi. For example, the first to ith bit lines BL1 to BLi may extend along the Y direction, and be disposed to be spaced apart from each other along an X direction. The first to ith memory blocks BLK1 to BLKi may be isolated from each other by a slit SLT.

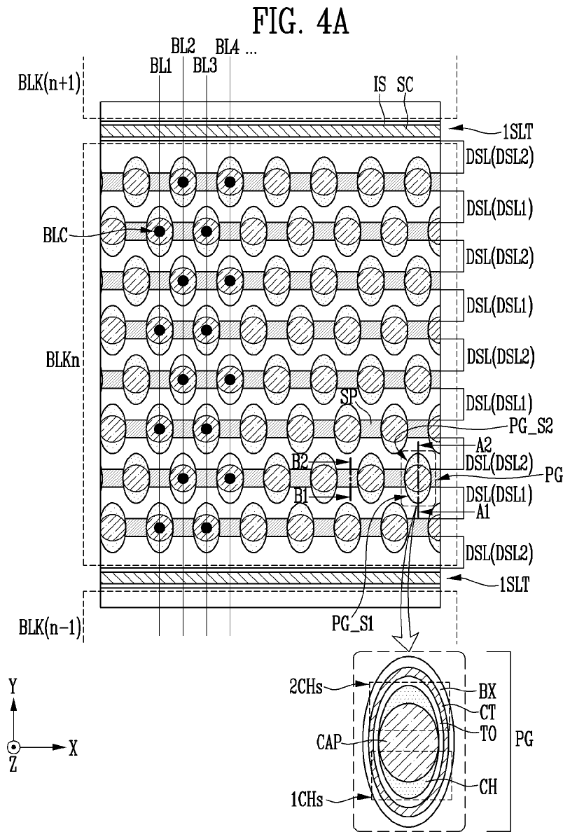

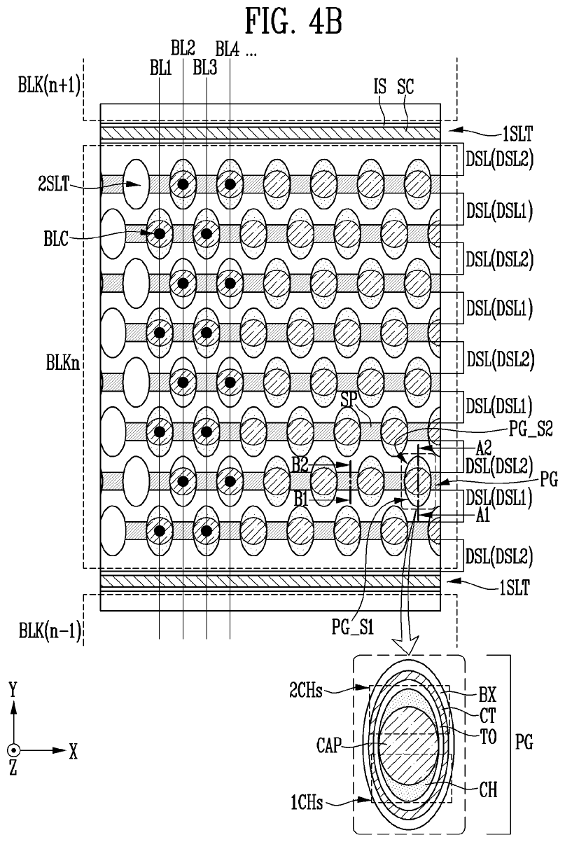

FIGS. 4A and 4B are views illustrating layouts of a memory device in accordance with an embodiment of the present disclosure.

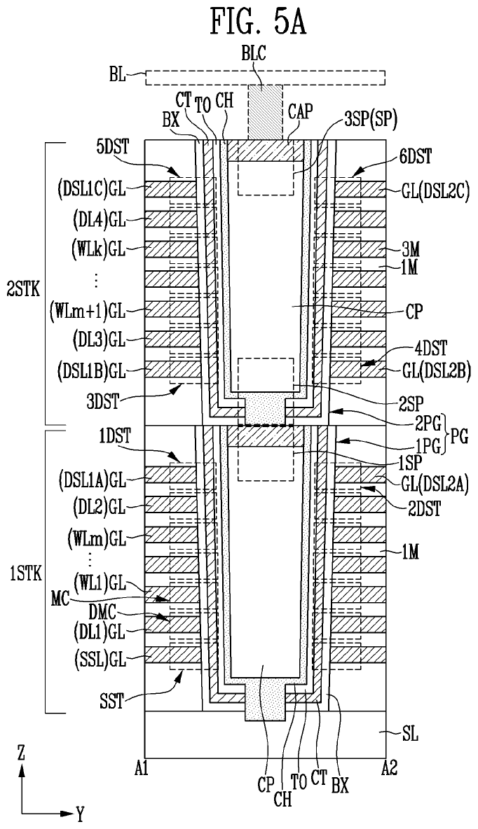

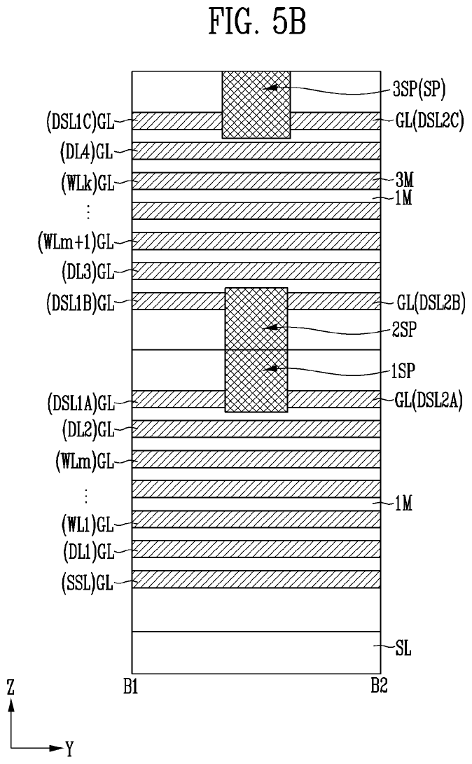

Referring to FIGS. 4A and 4B, a plurality of memory blocks BLK(n−1), BLKn, and BLK(n+1) of the memory device may be spaced apart from each other by first slits 1SLT. In an embodiment, an (n−1)th memory block BLK(n−1), an nth memory block BLKn, and an (n+1)th memory block BLK(n+1) may be disposed to be spaced apart from each other in the Y direction. The plurality of memory blocks BLK(n−1), BLKn, and BLK(n+1) may be configured identically to one another, and be distinguished from each other by the first slits 1SLT. Each of the first slits 1SLT may include a slit insulating layer IS and a source contact SC. The slit insulating layer IS may electrically block memory blocks from each other. The source contact SC may be in contact with a source line (e.g., SL shown in FIGS. 5A and 5B) formed under the memory blocks, and transfer a source line voltage generated in a voltage generating circuit to the source line.

The plurality of memory blocks BLK(n−1), BLKn, and BLK(n+1) may be configured identically to one another, and therefore, FIGS. 4A and 4B representatively illustrate the nth memory block BLKn among the plurality of memory blocks BLK(n−1), BLKn, and BLK(n+1). Hereinafter, the structure of each of the plurality of memory blocks BLK(n−1), BLKn, and BLK(n+1) will be described based on the structure of the nth memory block BLKn.

The nth memory block BLKn may include a plurality of plugs PG. The plurality of plugs PG may be disposed on a plurality of columns. Plugs PG of each column may be arranged in the Y direction. For convenience of recognition, FIGS. 4A and 4B illustrate first, second, third, and fourth bit lines BL1, BL2, BL3, and BL4 among a plurality of bit lines of the memory device, and illustration of some bit lines arranged at both sides of the first, second, third, and fourth bit lines BL1, BL2, BL3, and BL4 is omitted. The first, second, third, and fourth bit lines BL1, BL2, BL3, and BL4 may be respectively connected to plugs PG of first, second, third, and fourth columns. Each of the plugs PG may be connected to a bit line corresponding thereto among the plurality of bit lines through a bit line contact BLC. For example, plugs which are arranged in the Y direction and are located on the first column among the plugs PG may be connected to the first bit line BL1 through bit line contacts BLC, and plugs located on the second column spaced apart from the first column in the X direction to be adjacent to the first column may be connected to the second bit line BL2 through bit line contacts BLC.

The nth memory block BLKn may include a plurality of gate lines stacked to be spaced apart from each other in the Z direction. The plurality of gate lines may include source select lines (e.g., SSL shown in FIGS. 5A and 5B), word lines (e.g., WL shown in FIGS. 5A and 5B), and drain select lines (e.g., DSL shown in FIGS. 5A and 5B). The plurality of gate lines may further include dummy gate lines (e.g., DL shown in FIGS. 5A and 5B). Since the plurality of memory blocks BLK(n−1), BLKn, and BLK(n+1) are distinguished from each other by the first slits 1SLT, gate lines included in different memory blocks may be isolated from each other by the first slits 1SLT. For example, gate lines included in the (n−1)th memory block BLK(n−1) and gate lines included in the nth memory block BLKn may be isolated from each other through the first slit 1SLT.

The nth memory block BLKn may include at least one isolation pattern SP. The isolation pattern SP may be a structure for isolating select lines formed in the same layer from each other. For example, the isolation pattern SP may be a structure for isolating drain select lines DSL formed in the same layer from each other. In an embodiment, the nth memory block BLKn may include a plurality of drain select lines DSL which are disposed in the same layer and are isolated from each other in a direction intersecting the bit lines (e.g., BL1, BL2, BL3, and BL4). The plurality of drain select lines DSL may include a first drain select line DSL1 adjacent to a first side portion PG_S1 of the plug PG and a second drain select line DSL2 adjacent to a second side portion PG_S2 of the plug PG. Each of first drains select lines DSL1 and each of second drain select lines DSL2 constitute one string. Specifically, among plugs PG arranged on a plurality of rows in the X direction, a first drain select line DSL1 adjacent to first side portions PG_S1 of plugs PG arranged on a first row and a second drain select line DSL2 adjacent to second side portions PG_S2 of the plugs PG arranged on the first row constitute one string, and a first drain select line DSL1 adjacent to first side portions PG_S1 of plugs PG arranged on a second row and a second drain select line DSL2 adjacent to second side portions PG_S2 of the plugs PG arranged on the second row constitute separate one string. In addition, a first drain select line and a second drain select line, which are adjacent to the first slits 1SLT, constitute one string. The isolation pattern SP may be disposed between a first drain select line DSL1 and a second drain select line DSL2, and isolate the first drain select line DSL1 and the second drain select line DSL2 from each other.

The isolation pattern SP may be formed of an insulating material, to electrically isolate the drain select lines DSL from each other. For example, the isolation patterns SP may be formed of an oxide layer or a silicon oxide layer.

Referring to the layouts shown in FIGS. 4A and 4B, the plurality of plugs PG may be arranged as a plurality of rows between adjacent first slits 1SLT. The plugs PG may be disposed to be spaced apart from each other along a first direction (e.g., the X direction), and be disposed to be spaced apart from each other along a second direction (e.g., the Y direction) intersecting the first direction.

The isolation patterns SP may extend along the first direction (e.g., the X direction) and be disposed to be spaced apart from each other along the second direction (e.g., the Y direction) intersecting the first direction. The isolation pattern SP may be alternately disposed with the plug PG in a direction intersecting the plurality of bit lines (e.g., BL1, BL2, BL3, and BL4). In an embodiment, the isolation pattern SP and the plug PG may be alternately disposed in the X direction. The isolation pattern SP may overlap with a portion of the plug PG. More specifically, the isolation pattern SP may be directly connected to a portion of the plug PG between the first side portion PG_S1 and the second side portion PG_S2. However, the present disclosure is not limited thereto, and the isolation pattern SP may extend in a direction (e.g., the X direction) intersecting the plurality of bit lines to intersect the plug PG.

With reference to enlarged views shown in FIGS. 4A and 4B, a structure of the plugs PG will be described in detail as follows. Each of the plugs PG may include a capping layer CAP, a channel layer CH, a tunnel insulating layer TO, a charge trap layer CT, and a blocking layer BX. Although not shown in FIGS. 4A and 4B, a core pillar may be formed on the bottom of the capping layer CAP. For example, the core pillar may be formed of an insulating material or a conductive material. Each of the core pillar and the capping layer CAP may be formed to isolate the channel layer CH into a first sub-channel layer 1CHs and a second sub-channel layer 2CHs. For example, when the plug PG is formed in an elliptical shape, each of the core pillar and the capping layer CAP may be formed to be in contact with the tunnel insulating layer TO in a minor axis direction of the plug PG. The first sub-channel layer 1CHs and the second sub-channel layer 2CHs may be spaced apart from each other in a major axis direction of the plug PG with the core pillar or the capping layer CAP, which is interposed therebetween. The channel layer CH may be formed of a semiconductor material. For example, the channel layer CH may be formed of a poly-silicon layer. The tunnel insulating layer TO may be formed to surround the channel layer CH, and be formed of an insulating material. For example, the tunnel insulating layer TO may be formed of an oxide layer or a silicon oxide layer. The charge trap layer CT may be formed to surround the tunnel insulating layer TO, and be formed of a material in which charges can be trapped. For example, the charge trap layer CT may be formed of a nitride layer. The blocking layer BX may be formed to surround the charge trap layer CT, and be formed of an insulating material. For example, the blocking layer BX may be formed of an oxide layer or a silicon oxide layer. The capping layer CAP may be formed of a doped semiconductor layer. In an embodiment, the capping layer CAP may be formed of n-type doped silicon.

In accordance with the above-described embodiment of the present disclosure, although the first sub-channel layer 1CHs and the second sub-channel layer 2CHs of the plug PG are connected to the same bit line (e.g., BL1) via the capping layer CAP and the bit line contact BLC, the first sub-channel layer 1CHs and the second sub-channel layer 2CHs can be individually controlled through the first drain select line DSL1 and the second drain select line DSL2, which are isolated from each other.

Referring to FIG. 4A, plugs PG constituting a plurality of rows may be disposed to be spaced apart from each other at the same distance in the first direction (e.g., the X direction) and the second direction (e.g., the Y direction) intersecting the first direction. However, the present disclosure is not limited thereto. For example, the plugs PG may be disposed to be spaced apart from each other at different distances in the first direction, and be disposed to be spaced apart from each other at the same distance in the second direction. In another example, the plugs PG may be disposed to be spaced apart from each other at different distances in the second direction, and be disposed to be spaced apart from each other at the same distance in the first direction.

Referring to FIG. 4B, the nth memory block BLKn may further include at least one second slit 2SLT. Plugs PG constituting a plurality of rows may be disposed at both sides of the second slit 2SLT. Plugs PG adjacent to each other with the second slit 2SLT interposed therebetween may be disposed to be spaced apart from each other at a distance wider than a distance between plugs PG adjacent to each other without interposition of the second slit 2SLT. The second slit 2SLT is not limited to a hole type shown in FIG. 4B, and may be formed in various shapes. The second slit 2SLT may partially overlap with the isolation pattern SP. Specifically, a portion of the second slit 2SLT between one portion and the other portion of the second slit 2SLT may be in contact with the isolation pattern SP. In addition, the second slits 2SLT are not connected to the plurality of bit lines included in the memory device. For example, the first, second, third, and fourth bit lines BL1, BL2, BL3, and BL4 are merely connected respectively to the plugs PG through the bit line contacts BLC, and the second slits 2SLT are not connected to the first, second, third, and fourth bit lines BL1, BL2, BL3, and BL4.

FIGS. 5A and 5B are views illustrating sections of a memory device in accordance with an embodiment of the present disclosure. A section of the memory device taken along line A1-A2 shown in FIGS. 4A and 4B is illustrated in FIG. 5A, and a section of the memory device taken along line B1-B2 shown in FIGS. 4A and 4B is illustrated in FIG. 5B.

The memory device may include a first stack structure 1STK and a second stack structure 2STK. The second stack structure 2STK may be disposed on the first stack structure 1STK. The stacked direction of the first stack structure 1STK and the second stack structure 2STK may be the Z direction. Each of the plugs PG may be divided into a first plug 1PG included in the first stack structure 1STK and a second plug 2PG included in the second stack structure 2STK. The first plug 1PG may extend along a vertical direction of the first stack structure 1STK to be connected to a source line SL, and the second plug 2PG may extend along the vertical direction of the second stack structure 2STK to be connected to the first plug 1PG. That is, the first plug 1PG and the second plug 2PG may be aligned in a direction extending along the vertical direction of the first and second stack structures 1STK and 2STK. A bit line BL and a bit line contact BLC may be formed on the top of the second plug 2PG. Each plug PG may be connected to the bit line BL and the source line SL. For example, the first and second plugs 1PG and 2PG may be connected to the bit line BL through the bit line contact BLC formed on the second plug 2PG. The first and second plugs 1PG and 2PG may be connected to the source line SL on the bottom of the first plug 1PG. In an embodiment, the first plug 1PG and the second plug 2PG may be aligned in a direction vertical to the select lines of the first group as, for example, shown in FIG. 5A.

Each of the first and second stack structures 1STK and 2STK may include a plurality of gate lines GL spaced apart from each other in the Z direction. The plurality of gate lines GL may be alternately disposed with a plurality of first material layers 1M in the Z direction. The plurality of first material layers 1M may be formed of an insulating material to insulate the plurality of gate lines GL formed of a conductive material from each other. The plurality of gate lines GL may include a source select line SSL, a plurality of word lines WL1 to WLk (k is a natural number of 2 or more), drain select lines DSL1A and DSL2A of a first group, drain select lines DSL1B and DSL2B of a second group, and drain select lines DSL1C and DSL2C of a third group.

The first stack structure 1STK may include the source select line SSL, word lines WL1 to WLm (m is a natural number smaller than k) of a first group, which are stacked to be spaced apart from each other in the Z direction from the source select line SSL, and the drain select lines DSL1A and DSL2A of the first group. One or two or more gate lines GL on the source line SL among the gate lines GL of the first stack structure 1STK may be used as the source select line SSL. One or two or more gate lines under the second stack structure 2STK among the gate lines GL of the first stack structure 1STK may be used as the drain select lines DSL1A and DSL2A of the first group. The word lines WL1 to WLm of the first group may be spaced apart from each other in the Z direction between the source select line SSL and the drain select lines DSL1A and DSL2A of the first group. The gate lines GL of the first stack structure 1STK may further include at least one of a first dummy word line DL1 and a second dummy word line DL2. The first dummy word line DL1 may be disposed between the source select line SSL and the word lines WL1 to WLm of the first group. The first dummy word line DL1 may be disposed below the word lines WL1 to WLm of the first group. The second dummy word line DL2 may be disposed between the word lines WL1 to WLm of the first group and the drain select lines DSL1A and DSL2A of the first group.

A layout of the drain select lines DSL1A and DSL2A of the first group and a first isolation pattern 1SP may be designed identically to the layout of the drain select lines DSL and the isolation pattern SP, which is described with reference to FIGS. 4A and 4B. Accordingly, the drain select lines DSL1A and DSL2A of the first group may be divided into a first drain select line DSL1A of the first group and a second drain select line DSL2A of the first group by the first isolation pattern 1SP in contact with the first plug 1PG. Each of the source select line SSL, the first dummy word line DL1, the word lines WL1 to WLm of the first group, and the second dummy word line DL2 may continuously extend in a direction (e.g., the Y direction) intersecting the first isolation pattern 1SP to overlap with not only the first drain select line DSL1A of the first group but also the second drain select line DSL2A of the first group.

The second stack structure 2STK may include the drain select lines DSL1B and DSL2B of the second group, word lines WLm+1 to WLk of a second group, which are stacked to be spaced apart from each other in the Z direction from the drain select lines DSL1B and DSL2B of the second group, and the drain select lines DSL1C and DSL2C of the third group. One or two or more gate lines GL adjacent to the first stack structure 1STK among the gate lines GL of the second stack structure 2STK may be used as the drain select lines DSL1B and DSL2B of the second group. One or more two or more gate lines GL on the second stack structure among the gate lines GL of the second stack structure 2STK may be used as the drain select lines DSL1C and DSL2C of the third group. The word lines WLnn+1 to WLk of the second group may be spaced apart from each other in the Z direction between the drain select lines DSL1B and DSL2B of the second group and the drain select lines DSL1C and DSL2C of the third group. The gate lines GL of the second stack structure 2STK may further include at least one of a third dummy word line DL3 and a fourth dummy word line DL4. The third dummy word line DL3 may be disposed between the drain select lines DSL1B and DSL2B of the second group and the word lines WLm+1 to WLk of the second group, and the fourth dummy word line DL4 may be disposed between the word lines WLm+1 to WLk of the second group and the drain select lines DSL1C and DSL2C of the third group.

A layout of the drain select lines DSL1B and DSL2B of the second group and a second isolation pattern 2SP and a layout of the drain select lines DSL1C and DSL2C of the third group and a third isolation pattern 3SP may be designed identical to the layout of the drain select lines DSL and the isolation pattern SP, which is described with reference to FIGS. 4A and 4B. Accordingly, the drain select lines DSL1B and DSL2B of the second group may be isolated into a first drain select line DSL1B of the second group and a second drain select line DSL2B of the second group by the second isolation pattern 2SP in contact with the second plug PG2. In addition, the drain select lines DSL1C and DSL2C of the third group may be isolated into a first drain select line DSL1C of the third group and a second drain select line DSL2C of the third group by the third isolation pattern 3SP in contact with the second plug PG2. Each of the third dummy word line DL3, the word lines WLm+1 to WLk of the second group, and the fourth dummy word line DL4 may continuously extend in a direction (e.g., the Y direction) intersecting the second isolation pattern 2SP or the third isolation pattern 3SP to overlap with not only the first drain select line DSL1B of the second group and the first drain select line DSL1C of the third group but also the second drain select line DSL2B of the second group and the second drain select line DSL2C of the third group.

Each of the plurality of word lines WL1 to WLk may be connected to a gate of a memory cell MC corresponding thereto. The source select line SSL may be connected to a gate of a source select transistor SST, and each of the first, second, third, and fourth dummy word lines DL1, DL2, DL3, and DL4 may be connected to a gate of a dummy memory cell DMC corresponding thereto. Each of the drain select lines DSL1A, DSL1B, DSL1C, DSL2A, DSL2B, and DSL2C of the first, second, and third groups may be connected to a gate of a drain select transistor corresponding thereto. More specifically, the first drain select line DSL1A of the first group may be connected to a gate of a first drain select transistor 1DST, the second drain select line DSL2A of the first group may be connected to a gate of a second drain select transistor 2DST, the first drain select line DSL1B of the second group may be connected to a gate of a third drain select transistor 3DST, the second drain select line DSL2B of the second group may be connected to a gate of a fourth drain select transistor 4DST, the first drain select line DSL1C of the third group may be connected to a gate of a fifth drain select transistor 5DST, and the second drain select line DSL2C of the third group may be connected to a gate of a sixth drain select transistor 6DST.

The source select transistor SST may electrically connect or block the source line SL and a channel layer CH of the first plug 1PG to each other or from each other according to a voltage applied to the source select line SSL. The first, second, third, and fourth drain select transistors 1DST, 2DST, 3DST, and 4DST may electrically connect or block the channel layer CH of the first plug 1PG and a channel layer CH of the second plug 2PG to each other or from each other according to voltages applied to the drain select lines DSL1A, DSL2A, DSL1B, and DSL2B of the first and second groups. The fifth and sixth drain select transistors 5DST and 6DST may electrically connect or block the channel layer CH of the second plug 2PG and the bit line BL to each other or from each other according to the drain select lines DSL1C and DSL2C of the third group.

The first isolation pattern 1SP may be disposed in the first stack structure 1STK, and the second isolation pattern 2SP and the third isolation pattern 3SP may be disposed in the second stack structure 2STK. The first plug 1PG may include a portion overlapping with the first isolation pattern 1SP. In an embodiment, like the plug PG and the isolation pattern SP, which are shown in FIGS. 4A and 4B, the first plug 1PG and the first isolation pattern 1SP may be alternately disposed in the X direction. The second plug 2PG may include a portion overlapping with the second isolation pattern 2SP and a portion overlapping with the third isolation pattern 3SP. In an embodiment, an arrangement of the second plug 2PG and the second isolation pattern 2SP and an arrangement of the second plug 2PG and the third isolation pattern 3SP may be identical to the arrangement of the plug PG and the isolation pattern SP, which are shown in FIGS. 4A and 4B.

In accordance with embodiments of the present disclosure, the drain select lines DSL1A and DSL2A of the first group of the first stack structure 1STK may be isolated into the first drain select line DSL1A of the first group, which is disposed at one side of the first plug 1PG, and the second drain select line DSL2A of the first group, which is disposed at the other side of the first plug 1PG by the first isolation pattern 1SP. Accordingly, a current flow path may be locally formed in the channel layer CH of the first plug 1PG by controlling voltages applied to the first drain select line DSL1A of the first group and the second drain select line DSL2A of the first group. Similarly, the drain select lines DSL1B and DSL2B of the second group of the second stack structure 2STK may be isolated into the first drain select line DSL1B of the second group and the second drain select line DSL2B of the second group, which can control whether a current flow path is locally formed in the channel layer CH of the second plug 2PG, by the second isolation pattern 2SP. In addition, the drain select lines DSL1C and DSL2C of the third group of the second stack structure 2STK may be isolated into the first drain select line DSL1C of the third group and the second drain select line DSL2C of the second group, which can control whether a current flow path is locally formed in the channel layer CH of the second plug 2PG, by the third isolation pattern 3SP.

As described with reference to FIGS. 4A and 4B, each of the first plug 1PG and the second plug 2PG may include a core pillar CP, a capping layer CAP, the channel layer CH, a tunnel insulting layer TO, a charge trap layer CT, and a blocking layer BX. The channel layer CH of the first plug 1PG may extend a sidewall and a bottom surface of a core pillar CP of the first plug 1PG. The channel layer CH of the first plug 1PG may be in contact with the source line SL along a vertical hole formed by partially removing a tunnel insulating layer TO, a charge trap layer CT, and a blocking layer BX of the first plug 1PG. The channel layer CH of the second plug 2PG may extend along a sidewall and a bottom surface of a core pillar CP of the second plug 2PG. The channel layer CH of the second plug 2PG may be in contact with a capping layer CAP of the first plug 1PG along a vertical hole formed by partially removing a tunnel insulating layer TO, a charge trap layer CT, and a blocking layer BX of the second plug 2PG.

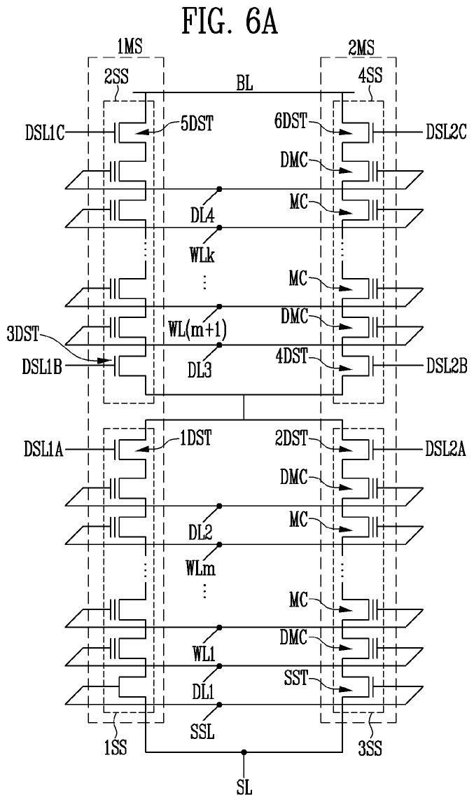

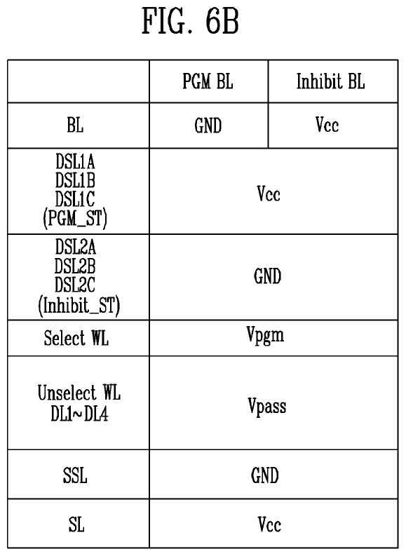

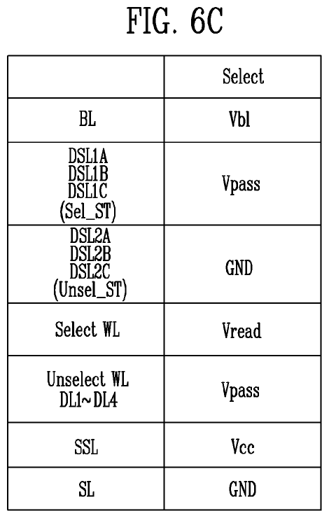

FIG. 6A is a circuit diagram illustrating a structure of strings in accordance with an embodiment of the present disclosure.

Referring to FIG. 6A, strings may be defined by the channel layer CH of the first plug 1PG and the channel layer CH of the second plug 2PG, which are shown in FIG. 5A. The strings may be isolated into a first main string 1MS and a second main string 2MS. The first main string 1MS may include a source select transistor SST, a plurality of memory cells MC, at least one dummy memory cell DMC, and first, third, and fifth drain select transistors 1DST, 3DST, and 5DST, which are connected in series by the channel layer CH of the first plug 1PG and the channel layer CH of the second plug 2PG, which are shown in FIG. 5A. The second main string 2MS may include a source select transistor SST, a plurality of memory cells MC, at least one dummy memory cell DMC, and second, fourth, and sixth drain select transistors 2DST, 4DST, and 6DST, which are connected in series by the channel layer CH of the first plug 1PG and the channel layer CH of the second plug 2PG, which are shown in FIG. 5A.

Each of the channel layer CH of the first plug 1PG and the channel layer CH of the second plug 2PG, which are shown in FIG. 5A, may be divided into the first sub-channel layer 1CHs and the second sub-channel layer 2CHs, which are shown in FIGS. 4A and 4B. The source select transistor SST, the plurality of memory cells MC, the at least one dummy memory cell DMC, and the first, third, and fifth drain select transistors 1DST, 3DST, and 5DST of the first main string 1MS may be connected in series along a portion of each of the channel layer CH of the first plug 1PG and the channel layer CH of the second plug 2PG, which correspond to the first sub-channel layer. The source select transistor SST, the plurality of memory cells MC, the at least one dummy memory cell DMC, and the second, fourth, and sixth drain select transistors 2DST, 4DST, and 6DST of the second main string 2MS may be connected in series along another portion of each of the channel layer CH of the first plug 1PG and the channel layer CH of the second plug 2PG, which correspond to the second sub-channel layer.

The first main string 1MS and the second main string 2MS may be connected to the same bit line BL, and be connected to the same source line SL. Each of a source select line SSL, first, second, third, and fourth dummy word lines DL1, DL2, DL3, and DL4, and a plurality of word lines WL1 to WLk may be connected to the first main string 1MS and the second main string 2MS. The first main string 1MS and the second main string 2MS may be individually controlled by first drain select lines DSL1A, DSL1B, and DSL1C of firsts, second, and third groups and second drain select lines DSL1B, DSL2B, and DSL2C of the first, second, and third groups.

The first main string 1MS may include first and second sub-strings 1SS and 2SS, and the second main string 2MS may include third and fourth sub-strings 3SS and 4SS. The first sub-string 1SS may include the source select transistor SST, a memory cell MC, a dummy memory cell DMC, and the first drain select transistor 1DST, which are connected in series by the channel layer CH of the first plug 1PG shown in FIG. 5A. The second sub-string 2SS may include the third drain select transistor 3DST, a dummy memory cell DMC, a memory cell MC, and the fifth drain select transistor 5DST, which are connected in series by the channel layer CH of the second plug 2PG shown in FIG. 5A. The third sub-string 3SS may include the source select transistor SST, a memory cell MC, a dummy memory cell DMC, and the second drain select transistor 2DST, which are connected in series by the channel layer CH of the first plug 1PG shown in FIG. 5A. The fourth sub-string 4SS may include the fourth drain select transistor 4DST, a dummy memory cell DMC, a memory cell MC, and the sixth drain select transistor 6DST, which are connected in series by the channel layer of the second plug 2PG.

The first sub-string 1SS may be electrically connected to or blocked from the second sub-string 2SS by the first and third drain select transistors 1DST and 3DST. When the first and third drain select transistors 1DST and 3DST are turned off, the first and second sub-strings 1SS and 2SS may be electrically blocked from each other. In an embodiment, when the first and third drain select transistors 1DST and 3DST are turned off, the first and second sub-strings 1SS and 2SS may be electrically isolated or disconnected from each other. When the first and third drain select transistors 1DST and 3DST are turned on, the first and second sub-strings 1SS and 2SS may be electrically connected to each other.

The third sub-string 3SS may be electrically connected to or blocked from the fourth sub-string 4SS by the second and fourth drain select transistors 2DST and 4DST. When the second and fourth drain select transistors 2DST and 4DST are turned off, the third and fourth sub-strings 3SS and 4SS may be electrically blocked from each other. In an embodiment, when the second and fourth drain select transistors 2DST and 4DST are turned off, the third and fourth sub-strings 3SS and 4SS may be electrically isolated or disconnected from each other. When the second and fourth drain select transistors 2DST and 4DST are turned on, the third and fourth sub-strings 3SS and 4SS may be electrically connected to each other.

The first drain select lines DSL1A, DSL1B, and DSL1C of the first, second, and third groups may be individually connected to the first, third, and fifth drain select transistors 1DST, 3DST, and 5DST of the first main string 1MS. A structure for connecting the first drain select lines DSL1A, DSL1B, and DSL1C of the first, second, and third groups to each other may be separately provided such that the same voltage can be applied to the first drain select lines DSL1A, DSL1B, and DSL1C of the first, second, and third groups. In an embodiment, contact structures may be respectively connected to the first drain select lines DSL1A, DSL1B, and DSL1C of the first, second, and third groups, and a line connecting the contact structure may be provided on the contact structures. The first, third, and fifth drain select transistors 1DST, 3DST, and 5DST may be driven at the same voltage in program, erase, and read operations of the memory device.

The second drain select lines DSL2A, DSL2B, and DSL2C of the first, second, and third groups may be individually connected to the second, fourth, and sixth drain select transistors 2DST, 4DST, and 6DST of the second main string 2MS. A structure for connecting the second drain select lines DSL2A, DSL2B, and DSL2C of the first, second, and third groups to each other may be separately provided such that the same voltage can be applied to the second drain select lines DSL2A, DSL2B, and DSL2C of the first, second, and third groups. In an embodiment, contact structures may be respectively connected to the second drain select lines DSL2A, DSL2B, and DSL2C of the first, second, and third groups, and a line for connecting the contact structures may be provided on the contact structures. The second, fourth, and sixth drain select transistors 2DST, 4DST, and 6DST may be driven at the same voltage in program, erase, and read operations of the memory device.

FIG. 6B is a diagram illustrating voltages applied to gate lines in a program operation in accordance with an embodiment of the present disclosure.

Referring to FIG. 6B, in a program operation, a memory cell which becomes a program target is defined as a program target cell. A word line connected to the program target cell is defined as a select word line Select WL, and each of the other word lines connected to the same string as the select word line Select WL is defined as an unselect word line Unselect WL. The select word line Select WL may surround the plurality of plugs PG shown in FIGS. 4A and 4B. As shown in FIGS. 4A and 4B, the plurality of plugs PG may be connected to a plurality of bit lines (e.g., BL1, BL2, BL3, and BL4). A bit line connected to the program target cell among the bit lines shown in FIGS. 4A and 4B may be defined as a program bit line PGM BL, and each of the other bit lines may be defined as a program inhibit bit line Inhibit BL. For example, referring to FIGS. 4A and 4B, when a memory cell of a string connected to the first bit line BL1 is to be programmed, the first bit line BL1 may be defined as a program bit line PGM BL, and each of the second, third, and fourth bit lines BL2, BL3, and BL4 may be defined as a program inhibit bit line Inhibit BL. The program bit line PGM BL may be connected to the first main string 1MS and the second main string 2MS, which are shown in FIG. 6A. A string including the program target cell, which is selected from the first and second main strings 1MS and 2MS shown in FIG. 6A, may be defined as a program string PGM_ST, and the other may be defined as a program inhibit string Inhibit_ST. Hereinafter, the program operation will be described by exemplifying a case where the first main string 1MS shown in FIG. 6A is the program string PGM_ST and the second main string 2MS shown in FIG. 6A is the program inhibit string Inhibit_ST.

Referring to FIGS. 6A and 6B, in the program operation, a ground voltage GND may be applied to the program bit line PGM BL, and a power voltage Vcc may be applied to the program inhibit bit line Inhibit BL. The power voltage Vcc may be applied to drain select lines (e.g., DSL1A, DSL1B, DSL1C) connected to the program string PGM_ST, and the ground voltage GND may be applied to drain select lines (e.g., DSL2A, DSL2B, and DSL2C) of the program inhibit string Inhibit_ST. A program voltage Vpgm may be applied to the select word line Select WL, and a pass voltage Vpass may be applied to the unselect word lines Unselect WL and the dummy word lines DL1, DL2, DL3, and DL4. The ground voltage GND may be applied to the source select line SSL, and the power voltage Vcc may be applied to the source line SL.

FIG. 6C is a diagram illustrating voltages applied to the gate lines in a read operation in accordance with an embodiment of the present disclosure.

Referring to FIGS. 6A and 6C, in a read operation, a word line connected to a selected memory cell is defined as a select word line Select WL, and each of the other word lines connected to the same string as the select word line Select WL is defined as an unselect word line Unselect WL. The selected memory cell may be included in one of the first main string 1MS and the second main string 2MS, which are connected to the bit line BL. The string including the selected memory cell may be defined as a select string Sel_ST, and the other may be defined as an unselect string Unsel_ST. Hereinafter, the read operation will be described by exemplifying a case where the first main string 1MS is the select string Sel_ST and the second main string 2MS is the unselect string Unsel_ST.

Referring to FIGS. 6A and 6C, in the read operation, a bit line voltage Vbl may be applied to the bit line BL. A pass voltage Vpass may be applied to drain select lines (e.g., DSL1A, DSL1B, and DSL1C) of the select string Sel_ST, and a ground voltage GND may be applied to drain select lines (e.g., DSL2A, DSL2B, and DSL2C) of the unselect string Unsel_ST. A read voltage Vread may be applied to the select word lines Select WL, and the pass voltage Vpass may be applied to the unselect word lines Unselect WL and the dummy word lines DL1, DL2, DL3, and DL4. A power voltage Vcc may be applied to the source select line SSL, and the ground voltage GND may be applied to the source line SL.

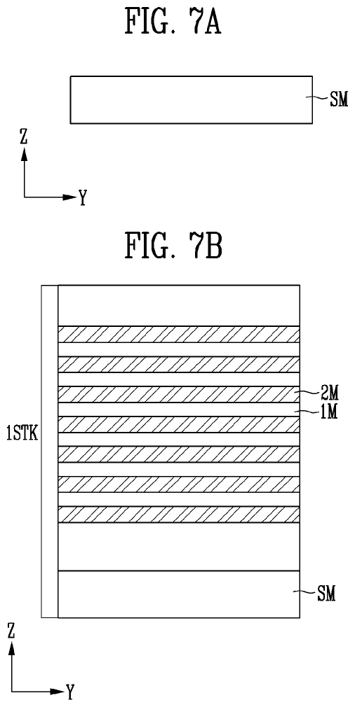

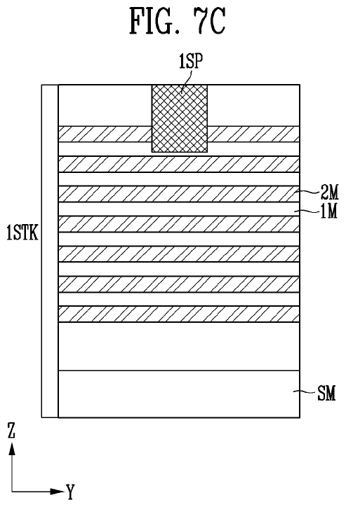

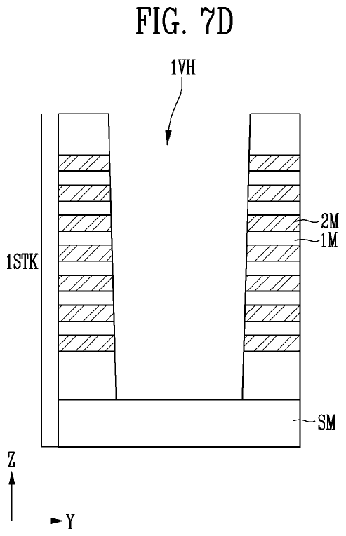

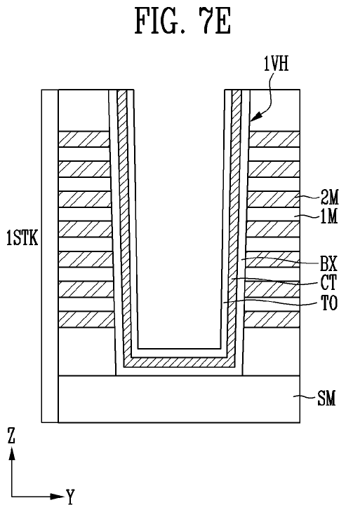

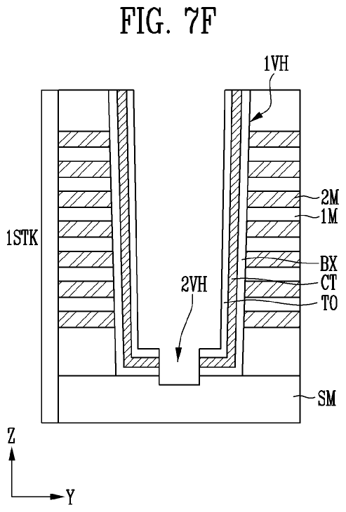

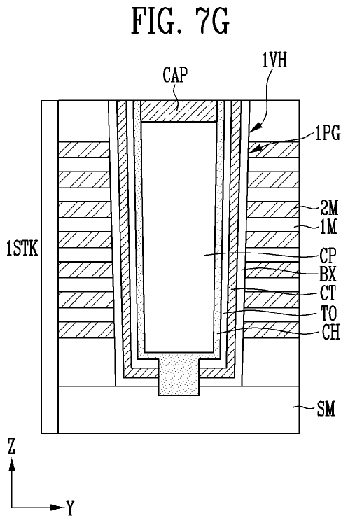

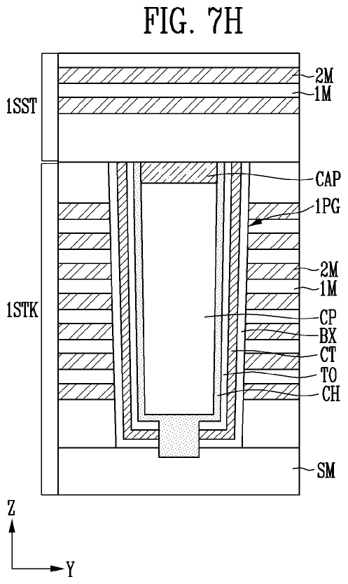

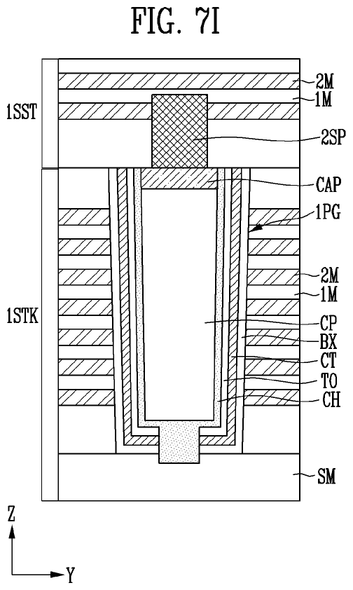

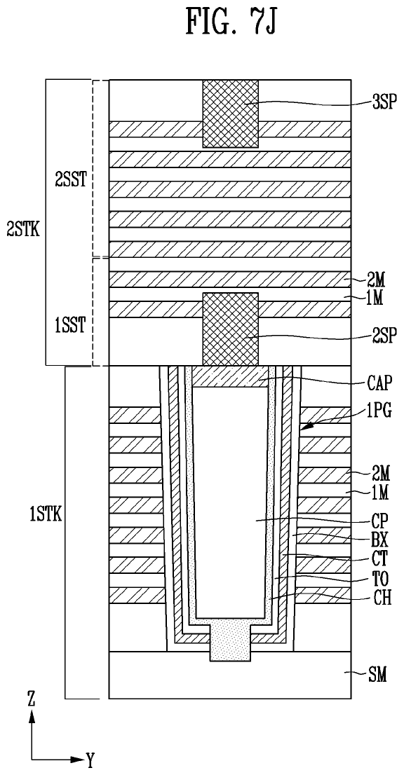

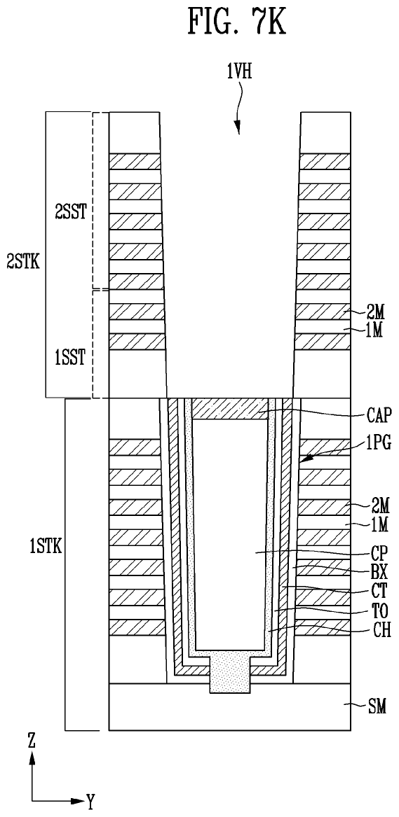

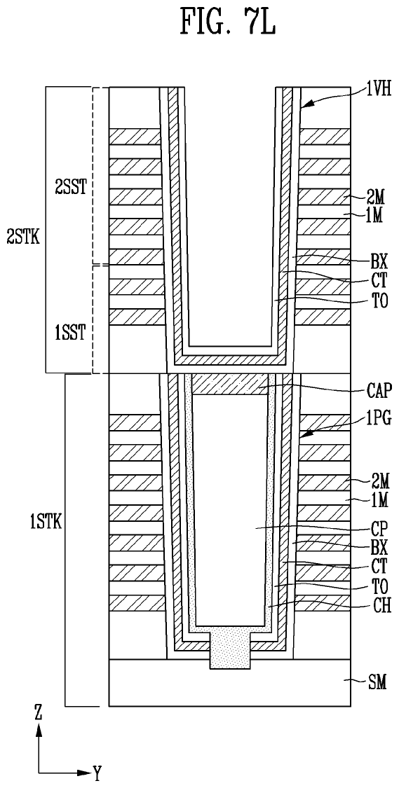

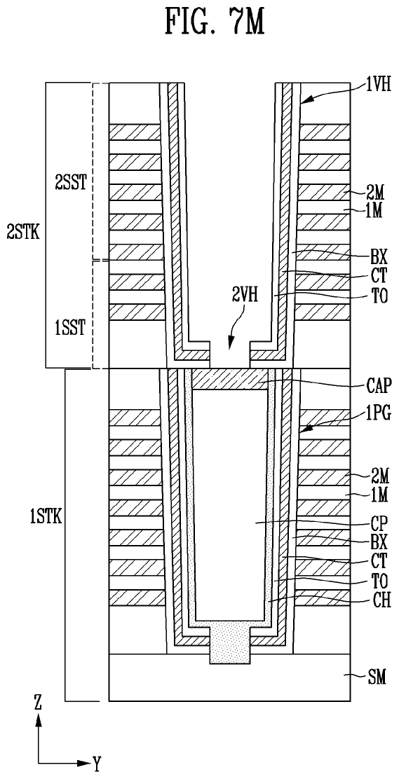

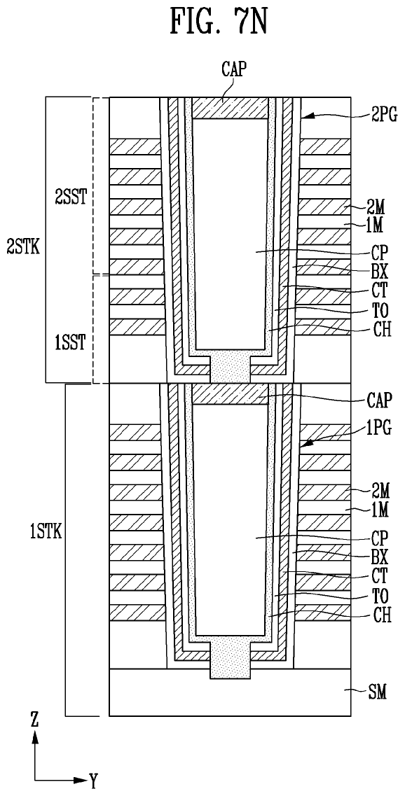

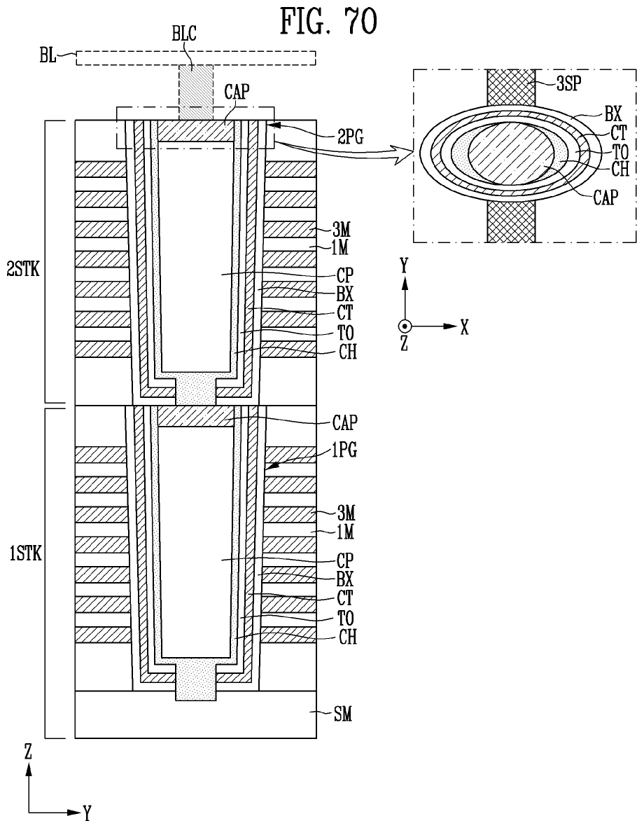

FIGS. 7A to 7O are sectional views illustrating a manufacturing method of a memory device in accordance with an embodiment of the present disclosure.

Referring to FIG. 7A, a source layer SM may be stacked on a lower structure (not shown). The lower structure (not shown) may be a substrate or a structure including peripheral circuits. Since the source layer SM is a layer used as a source line, the source layer SM may be formed of a conductive material. For example, the source layer SM may be formed of a conductive material such as poly-silicon, tungsten or nickel.

Referring to FIG. 7B, first and second material layers 1M and 2M may be alternately stacked on the top of the source layer SM. For example, when a first material layer 1M is formed on the top of the source layer SM, a second material layer 2M may be formed on the top of the first material layer 1M, and a first material layer 1M may be again formed on the top of the second material layer 2M. The first material layer 1M may be formed of an insulating material. For example, the first material layer 1M may be formed of an oxide layer or a silicon oxide layer. The second material layer 2M may be formed of a material which may be removed in a subsequent process. Therefore, the second material layer 2M may be formed of a conductive material having an etch selectivity different from an etch selectivity of the first material layer 1M. For example, the second material layer 2M may be formed of a poly-silicon layer, a metal or a nitride layer. The first material layer 1M may be formed at a lowermost end and an uppermost end in a structure in which the first and second material layers 1M and 2M are stacked. Accordingly, a first stack structure 1STK may be formed.

Referring to FIG. 7C, a first isolation pattern 1SP for isolating select lines of a first group from each other may be formed. An etching process for forming the first isolation pattern 1SP may be performed until the first material layer 1M is exposed such that the select lines of the first group, which are formed in the same layer, can be isolated from each other. For example, when two lines formed at an upper end among gate lines are specified as drain select lines, the first isolation pattern 1SP may be formed such that the two lines specified as the drain select lines are isolated from each other. The etching process for forming the first isolation pattern 1SP may be performed such that portions of the first and second material layers 1M and 2M are removed in the vertical direction. For example, the etching process for forming the first isolation pattern 1SP may be performed as an anisotropic dry etching process. Since the first isolation pattern 1SP electrically isolates some gate lines formed in the same layer from each other, the first isolation pattern 1SP may be formed of an insulating material. For example, the first isolation pattern 1SP may be formed of oxide or silicon oxide.

Referring to FIG. 7D, a first vertical hole 1VH may be formed, which exposes the source layer SM in a cell region of a memory block. An etching process for removing portions of the first and second material layers 1M and 2M may be performed to form the first vertical hole 1VH. The etching process may be performed as a dry etching process such that the first vertical hole 1VH is formed in a direction vertical to the substrate. The first vertical hole 1VH may be formed in a region for forming a plug. A major axis of the first vertical hole 1VH becomes the Y direction, and a minor axis of the first vertical hole 1VH becomes the X direction. When the etching process for forming the first vertical hole 1VH is ended, the source layer SM may be exposed through a bottom surface of the first vertical hole 1VH, and the first and second material layers 1M and 2M may be exposed through a side surface of the first vertical hole 1VH.

Referring to FIG. 7E, a blocking layer BX, a charge trap layer CT, and a tunnel insulating layer TO may be formed inside the first vertical hole 1VH. For example, the blocking layer BX may be formed along an inner surface of the first vertical hole 1VH formed in a cylindrical shape. The blocking layer BX may be formed in a cylindrical shape which is not entirely filled in the first vertical hole 1VH. Subsequently, the charge trap layer CT may be formed in a cylindrical shape along an inner surface of the blocking layer BX, and the tunnel insulating layer TO may be formed in a cylindrical shape along an inner surface of the charge trap layer CT.

Referring to FIG. 7F, a second vertical hole 2VH may be formed, which exposes the source layer SM. For example, an etching process for removing portions of the blocking layer BX, the charge trap layer CT, and the tunnel insulating layer TO may be performed so as to form the second vertical hole 2VH. The etching process may be performed as a dry etching process such that the second vertical hole 2VH is formed in the direction vertical to the substrate. The second vertical hole 2VH may be formed in a region for forming a channel layer such that the channel layer can be in contact with the source layer SM. Therefore, a bottom surface of the second vertical hole 2VH may be formed to have a width narrower than a width of a bottom surface of the tunnel insulating layer TO. When the etching process for forming the second vertical hole 2VH is ended, the source layer SM may be exposed through the bottom surface of the second vertical hole 2VH, and the blocking layer BX, the charge trap layer CT, and the tunnel insulating layer TO may be exposed through a side surface of the second vertical hole 2VH.

Referring to FIG. 7G, a first plug 1PG may be formed in the first stack structure 1STK. The first plug 1PG may include the blocking layer BX, the charge trap layer CT, the tunnel insulating layer TO, a channel layer CH, a core pillar CP, and a capping layer CAP. In succession to the blocking layer BX, the charge trap layer CT, and the tunnel insulating layer TO, which are formed in the cylindrical shape, the channel layer CH may be formed along an inner surface of the tunnel insulating layer TO. The core pillar CP may be filled in the first plug 1PG surrounded by the channel layer CH and the tunnel insulating layer TO. Specifically, the core pillar CP may be formed in a structure simultaneously in contact with the tunnel insulating layer TO and the channel layer CH. For example, when the first plug 1PG is formed in an elliptical layout, the core pillar CP may be formed to be in contact with the tunnel insulating layer TO in a minor axis direction of the ellipse and to be in contact with the channel layer CH in a major axis direction of the ellipse. The capping layer CAP may be formed on the top of the core pillar CP. Since the channel layer CH is formed along the inside of the second vertical hole 2VH, the channel layer CH may be in contact with the source layer SM.

Referring to FIG. 7H, a first sub-structure 1SST including select lines of a second group may be formed on the first stack structure 1STK. First and second material layers 1M and 2M may be alternately stacked on the first stack structure 1STK to form the first sub-structure 1SST. The first material layer 1M included in the first sub-structure 1SST may be formed of the same material as the first material layer 1M included in the first stack structure 1STK. The second material layer 2M included in the first sub-structure 1SST may be formed of the same material as the second material layer 2M included in the first stack structure 1STK. The first material layer 1M may be formed at a lowermost end and an uppermost end of the first sub-structure 1SST in which the first and second material layers 1M and 2M are stacked.

Referring to FIG. 7I, a second isolation pattern 2SP for isolating the select lines of the second group from each other. An etching process for forming the second isolation pattern 2SP may be performed until the first material layer 1M at a lower portion of the first sub-structure 1SST is exposed such that the select lines of the second group in the first sub-structure 1SST can be isolated from each other. The etching process for forming the second isolation pattern 2SP may be performed such that portions of the first and second material layers 1M and 2M are removed in the vertical direction. For example, the etching process for forming the second isolation pattern 2SP may be performed as an anisotropic dry etching process. Since the second isolation pattern 2SP electrically isolates the select lines of the second group from each other, the second isolation pattern 2SP may be formed of an insulating material. For example, the second isolation pattern 2SP may be formed of oxide or silicon oxide.

Referring to FIG. 73, a second sub-structure 2SST may be formed, which includes word lines and select lines of a third group on the select lines of the second group. The first sub-structure 1SST and the second sub-structure 2SST may form a second stack structure 2STK formed on the first stack structure 1STK. First and second material layers 1M and 2M may be alternately stacked on the first sub-structure 1SST so as to form the second sub-structure 2SST. The first material layer 1M included in the second sub-structure 2SST may be formed of the same material as the first material layer 1M included in the first stack structure 1STK. The second material layer 2M included in the second sub-structure 2SST may be formed of the same material as the second material layer 2M included in the first stack structure 1STK. The first material layer 1M may be formed at an uppermost end of the second sub-structure 2SST in which the first and second material layers 1M and 2M are stacked.

A third isolation pattern 3SP for isolating the select lines of the third group on the word lines of the second stack structure 2STK may be formed. An etching process for forming the third isolation pattern 3SP may be performed until the first material layer 1M of the second sub-structure 2SST is exposed such that the select lines of the third group in the second sub-structure 2SST can be isolated from each other. The etching process for forming the third isolation pattern 3SP may be performed such that portions of the first and second material layers 1M and 2M are removed in the vertical direction. For example, the etching process for forming the third isolation pattern 3SP may be performed as an anisotropic dry etching process. Since the third isolation pattern 3SP electrically isolates the select lines of the third group from each other, the third isolation pattern 3SP may be formed of an insulating material. For example, the third isolation pattern 3SP may be formed of oxide or silicon oxide.

Referring to FIG. 7K, a first vertical hole 1VH may be formed in the cell region of the memory block of the second stack structure 2STK. For example, an etching process for removing portions of the first and second material layers 1M and 2M may be performed. The etching process may be performed as a dry etching process such that the first vertical hole 1VH is formed in the vertical direction from the substrate. The first vertical hole 1VH may be formed in a region for forming a second plug. A major axis of the first vertical hole 1VH becomes the Y direction, and a minor axis of the first vertical hole 1VH becomes the X direction. When the etching process for forming the first vertical hole 1VH is ended, the capping layer CAP of the first plug 1PG of the first stack structure 1STK may be exposed through a bottom surface of the first vertical hole 1VH, and the first and second material layers 1M and 2M may be exposed through a side surface of the first vertical hole 1VH.

Referring to FIG. 7L, a blocking layer BX, a charge trap layer CT, and a tunnel insulating layer TO may be formed inside the first vertical hole 1VH. For example, the blocking layer BX may be formed along an inner surface of the first vertical hole 1VH formed in a cylindrical shape. The blocking layer BX may be formed in a cylindrical shape which is not entirely filled in the first vertical hole 1VH. Subsequently, the charge trap layer CT may be formed in a cylindrical shape along an inner surface of the blocking layer BX, and the tunnel insulating layer TO may be formed in a cylindrical shape along an inner surface of the charge trap layer CT.

Referring to FIG. 7M, a second vertical hole 2VH may be formed, which exposes the channel layer CH of the first stack structure 1STK. For example, an etching process for removing portions of the blocking layer BX, the charge trap layer CT, and the tunnel insulating layer TO may be performed. The etching process may be performed as a dry etching process such that the second vertical hole 2VH is formed in the vertical direction from the substrate. When the etching process for forming the second vertical hole 2VH is ended, the capping layer CAP of the first plug 1PG may be exposed through a bottom surface of the second vertical hole 2VH, and the bottom surface of the second vertical hole 2VH may be formed to have a width narrower than a width of a bottom surface of the tunnel insulating layer TO. The blocking layer BX, the charge trap layer CT, and the tunnel insulating layer TO may be exposed through a side surface of the second vertical hole 2VH.

Referring to FIG. 7N, a second plug 2PG may be formed in the second stack structure 2STK. The second plug 2PG may include the blocking layer BX, the charge trap layer CT, the tunnel insulating layer TO, a channel layer CH, a core pillar CP, and a capping layer CAP. In succession to the blocking layer BX, the charge trap layer CT, and the tunnel insulating layer TO, which are formed in the cylindrical shape in FIG. 7M, the channel layer CH may be formed in a cylindrical shape along an inner surface of the tunnel insulating layer TO. The core pillar CP may be filled in the second plug 2PG surrounded by the tunnel insulating layer TO and the channel layer CH. Specifically, the core pillar CP may be formed in a structure simultaneously in contact with the tunnel insulating layer TO and the channel layer CH. For example, when the second plug 2PG is formed in an elliptical layout, the core pillar CP may be formed to in contact with the tunnel insulating layer TO in a minor axis direction of the ellipse and to be in contact with the channel layer CH in a major axis direction of the ellipse. The capping layer CAP may be formed on the top of the core pillar CP. Since the channel layer CH is formed along the inside of the second vertical hole 2VH, the channel layer CH may be in contact with the capping layer CAP of the first plug 1PG. Accordingly, the second plug can be formed, which intersects word lines of a second group and select lines of second and third groups of the second stack structure.

After the second plug 2PG is formed, a subsequent process may be various. In an embodiment, when the structure shown in FIG. 4A is provided, the first slits (1SLT shown in FIG. 4) may be formed, which are adjacent to each other with plugs of a plurality of rows, interposed therebetween. The first slits 1SLT may extend in a row direction in which a plurality of plugs are arranged. The first slit 1SLT may be formed by etching portions of the first and second material layers 1M and 2M. Specifically, a slit insulating layer IS of the first slit 1SLT may be formed by stacking an insulating material after the portions of the first and second material layers 1M and 2M are etched, and a source contact SC may be formed by stacking a conductive material. The second material layer 2M may include at least one of poly-silicon and a metal. The second material layer 2M may be used as a material layer for a source select line, a word line, a dummy word line, and a drain select line.

In an embodiment, when the structure shown in FIG. 4B is provided, the first slits (1SLT shown in FIG. 4) adjacent to each other with plugs PG of a plurality of rows, interposed therebetween may be formed. In addition the second slit 2SLT may be formed between plugs PG constituting each row. Plugs PG may be located at both sides of the second slit 2SLT. The second material layer 2M may be poly-silicon, a metal, a nitride layer, or the like. When the second material layer 2M is poly-silicon or a metal, the second material layer 2M may be autonomously used as a material layer for a source select line, a word line, a dummy word line, and a drain select line. When the second material layer 2M is a nitride layer, the second material layer 2M may be replaced with a conductive material such as poly-silicon or a metal through a process shown in FIG. 7O, which will be described later.

Referring to FIG. 7O, when the second material layer 2M is a nitride layer, an etching process for removing the second material layer 2M through a slit may be performed. The second material layer 2M formed between the first slit 1SLT and the plugs PG may be removed through the first slits 1SLT shown in FIG. 4B, and the second material layer formed between the plugs PG constituting the plurality of rows may be removed through the second slits 2SLT. The etching process may be performed as a wet etching process using an etchant for allowing the first material layer 1M to remain and selectively removing the second material layer 2M. A third material layer 3M may be formed in a region in which the second material layer 2M. For example, the third material layer 3M may be formed between the first material layers 1M through the slit. Since the third material layer 3M is used as a gate line GL, the third material layer 3M may be formed of a conductive material. For example, the third material layer 3M may be formed of tungsten (W), cobalt (Co), nickel (Ni), molybdenum (Mo), silicon (Si), poly-silicon (poly-Si), or the like.

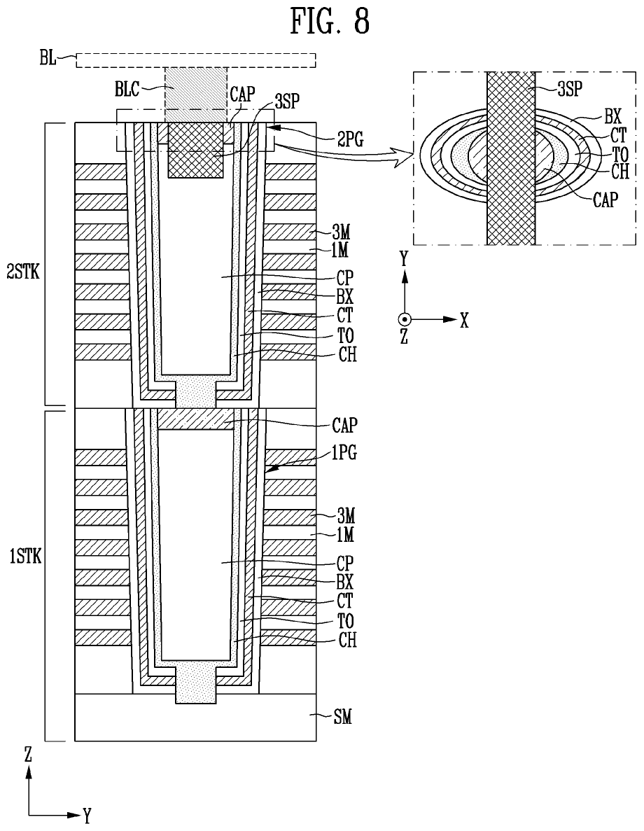

FIG. 8 is a sectional view illustrating a memory device in accordance with another embodiment of the present disclosure.

Referring to FIGS. 7J to 7O and 8, as compared with a case where the second plug 2PG is formed after the third isolation pattern 3SP is formed in FIGS. 7J to 7O, the case shown in FIG. 8 is an embodiment in which the second plug 2PG is formed and then the third isolation pattern 3SP is formed. The third isolation pattern 3SP may be formed along a vertical hole formed by partially etching the core pillar CP and the capping layer CAP at an upper portion of the second plug 2PG. The third isolation pattern 3SP may be formed such that the capping layer CAP is in contact with both sides of the third isolation pattern 3SP, and the core pillar CP surrounds a portion of the third isolation pattern 3SP. Thus, in the embodiment according to FIGS. 7J to 7O, referring to an enlarged view shown in FIG. 7O, the third isolation pattern 3SP is formed such that a region between one side portion and the other side portion of the second plug 2PG and the third isolation pattern 3SP do not overlap with each other. However, in the embodiment shown in FIG. 8, referring to an enlarged view shown in FIG. 8, the third isolation pattern 3SP is formed in a structure, a region between one side portion and the other side portion of the second plug 2PG and the third isolation pattern 3SP overlap with each other. Accordingly, the second plug can be formed, which intersect word lines of the second group, select lines of the second and third groups, and a portion of the third isolation pattern in the second stack structure.

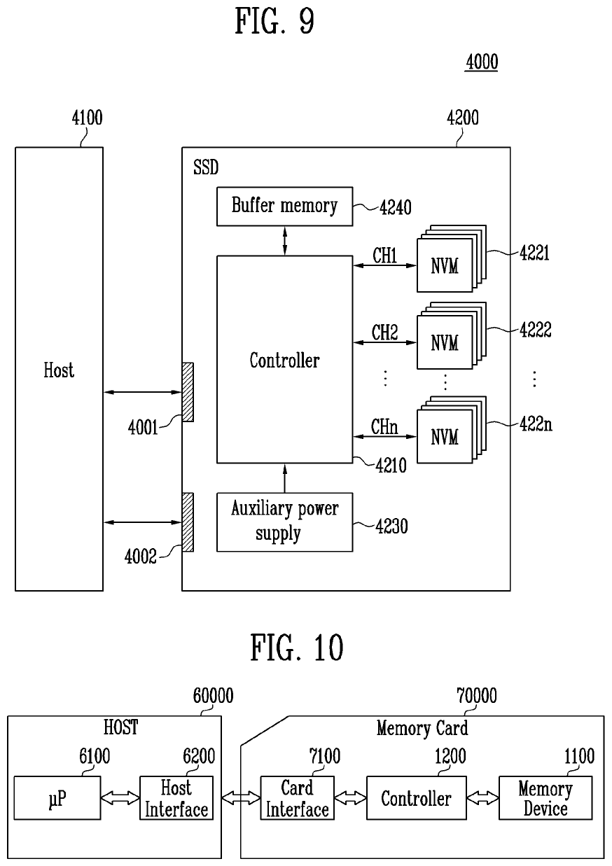

FIG. 9 is a diagram illustrating a Solid State Drive (SSD) system to which the memory device of the present disclosure is applied.

Referring to FIG. 9, the SSD system 4000 includes a host 4100 and an SSD 4200. The SSD 4200 may exchange a signal with the host 4100 through a signal connector 4001, and be supplied with power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be transmitted based on an interface between the host 4100 and the SSD 4200. For example, the signal may be defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power of the SSD 4200. Exemplarily, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may be used as a buffer memory of the SSD 4200. For example, the buffer memory 4240 may temporarily store data received from the host 4100 or data received from the plurality of memory devices 4221 to 422n, or temporarily store meta data (e.g., a mapping table) of the plurality of memory devices 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

FIG. 10 is a diagram illustrating a memory card system to which the memory device of the present disclosure is applied.

Referring to FIG. 10, the memory system 70000 may be implemented as a memory card or a smart card. The memory system 70000 may include a memory device 1100, a controller 1200, and a card interface 7100.

The memory device 1100 may be configured identically to the memory device 100 shown in FIG. 1.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor (μP) 6100.

In accordance with an embodiment of the present disclosure, the degree of integration of the memory device can be improved.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a first stack structure including a word line of a first group and select lines of a first group, wherein the select lines of the first group are isolated from each other;
a second stack structure including a word line of a second group and select lines of a second group, wherein the select lines of the second group are isolated from each other;
a first plug in the first stack structure;
a second plug connected to the first plug, the second plug being disposed in the second stack structure;
a first isolation pattern between the select lines of the first group; and
a second isolation pattern between the select lines of the second group,
wherein the select lines of the first group include a first select line of a first group and a second select line of a first group, which respectively surround a first side portion and a second side portion of the first plug at both sides of the first isolation pattern, and
wherein the select lines of the second group include a first select line of a second group and a second select line of a second group, which respectively surround a first side portion and a second side portion of the second plug at both sides of the second isolation pattern.

2. The memory device of claim 1, comprising:
select transistors of a first group, connected to the select lines of the first group, the select transistors of the first group included in the first plug; and
select transistors of a second group, connected to the select lines of the second group, the select transistors of the second group included in the second plug;
wherein the transistors of the first group include a first select transistor and a second select transistor, which are respectively connected to the first select line of the first group and the second select line of the first group, and
wherein the transistors of the second group include a third select transistor and a fourth select transistor, which are respectively connected to the first select line of the second group and the second select line of the second group.

3. The memory device of claim 2, wherein the first select transistor and the third select transistor are connected to each other along one side of the first plug and the second plug, and
the second select transistor and the fourth select transistor are connected to each other along the other side of the first plug and the second plug.

4. The memory device of claim 3, comprising:
a first sub-string in which a plurality of first memory cells, a source select transistor, and the first select transistor of the first stack structure are connected to each other;
a second sub-string in which a plurality of second memory cells and the third select transistor of the second stack structure are connected to each other;
a third sub-string in which the plurality of first memory cells, a source select transistor, and the second select transistor are connected to each other; and
a fourth sub-string in which the plurality of second memory cells and the fourth select transistor of the second stack structure are connected to each other,
wherein the first and second sub-strings are one of electrically blocked from and connected to each other by the first and third select transistors, and
the third and fourth sub-strings are one of electrically blocked from and connected to each other by the second and fourth select transistors.

5. The memory device of claim 4, wherein, in program, erase, and read operations of the memory device, the first and third transistors are driven by a first voltage, and the second and fourth transistors are driven by a second voltage, and wherein the first voltage is distinct from the second voltage.

6. The memory device of claim 1, wherein the first isolation pattern overlaps with a portion of the first plug, and
the second isolation pattern overlaps with a portion of the second plug.

7. The memory device of claim 1, wherein the first isolation pattern is in contact with a portion of the first plug between the first side portion and the second side portion of the first plug, and
the second isolation pattern is in contact with a portion of the second plug between the first side portion and the second side portion of the second plug.

8. The memory device of claim 1, wherein each of the first plug and the second plug includes a capping layer, a core pillar, a channel layer, a tunnel insulating layer, a charge trap layer, and a blocking layer.

9. The memory device of claim 8, wherein the core pillar and the capping layer of each of the first plug and the second plug isolate the channel layer into first and second sub-channel layers.

10. The memory device of claim 8, wherein the core pillar and the capping layer is in contact with the tunnel insulating layer in a minor axis direction of each of the first plug and the second plug.

11. The memory device of claim 1, wherein the second stack structure further includes:
select lines of a third group isolated from each other; and
a third isolation pattern between the select lines of the third group.

12. The memory device of claim 11, wherein the select lines of the third group include a first select line of a third group and a second select line of a third group,
and wherein the first select line of the third group and the second select line of the third group respectively surround a first side portion and a second side portion of the second plug at both sides of the third isolation pattern.

13. The memory device of claim 12, wherein the third isolation pattern is in contact with a portion of the second plug between the first side portion and the second side portion of the second plug.

14. The memory device of claim 12, further comprising fifth and sixth select transistors respectively connected to the first and second select lines of the third group,
wherein the fifth select transistor is connected to the first and third select transistors along one side of the first plug and the second plug, and
the sixth select transistor is connected to the second and fourth transistors along the other side of the first plug and the second plug.

15. The memory device of claim 1, further comprising:
a first dummy word line disposed below the word line of the first group; or
a second dummy word line disposed between the word line of the first group and the select lines of the first group.

16. The memory device of claim 1, wherein the first plug and the second plug are aligned in a direction vertical to the select lines of the first group.

17. A method of manufacturing a memory device, the method comprising:
forming, on a lower structure, a first stack structure including word lines of a first group and select lines of a first group, wherein the select lines of the first group are isolated from each other;
forming a first isolation pattern isolating the select lines of the first group from each other;
forming a first plug overlapping with the first isolation pattern in the first stack structure;
forming, on the first stack structure, a first sub-structure including select lines of a second group, wherein the select lines of the second group are isolated from each other;
forming a second isolation pattern isolating the select lines of the second group from each other; and
forming, above the select lines of the second group, a second sub-structure including word lines of a second group and select lines of a third group, wherein the select lines of the third group are isolated from each other.

18. The method of claim 17, wherein the forming of the first isolation pattern includes:
forming a vertical hole by etching the select lines of the first group; and
filling an insulating material in the vertical hole formed by etching the select lines of the first group.

19. The method of claim 17, wherein the forming of the first plug includes:
forming a first vertical hole by etching the word lines of the first group, the select lines of the first group, and a portion of the first isolation pattern;
forming a blocking layer, a charge trap layer, and a tunnel insulating layer along an inner wall of the first vertical hole;
forming a second vertical hole by etching the blocking layer, the charge trap layer, and the tunnel insulating layer; and
forming a channel layer, a core pillar, and a capping layer along an inner wall of the tunnel insulating layer and the second vertical hole.

20. The method of claim 17, wherein the forming of the second isolation pattern includes:
forming a vertical hole by etching the select lines of the second group; and
filling an insulating material in the vertical hole formed by etching the select lines of the second group.

21. The method of claim 17, further comprising:
forming a second plug intersecting the word lines of the second group and the select lines of the second and third groups in the first and second sub-structures; and
forming a third isolation pattern isolating the select lines of the third group from each other in the second sub-structure, the third isolation pattern being in contact with a portion of the second plug.

22. The method of claim 17, further comprising:
forming a third isolation pattern isolating the select lines of the third group from each other in the second sub-structure; and
forming a second plug intersecting the word lines of the second group, the select lines of the second and third groups, and a portion of the third isolation pattern.
